(19) United States
(12) Patent Application Publication
(10) Pub. No.: US 2024/0162871 A1
(43) Pub. Date: May 16, 2024

(54) BALANCED-UNBALANCED TRANSFORMER CIRCUIT AND AMPLIFIER CIRCUIT

(71) Applicant: Murata Manufacturing Co., Ltd., Kyoto (JP)

(72) Inventors: Masatoshi HASE, Kyoto (JP); Koudai SUGIYAMA, Kyoto (JP); Masamichi TOKUDA, Kyoto (JP); Seiko NETSU, Kyoto (JP)

(21) Appl. No.: 18/504,274

(22) Filed: Nov. 8, 2023

(30) Foreign Application Priority Data
Nov. 10, 2022 (JP) 2022-180502

(51) Int. Cl. H03F 3/45

(52) U.S. Cl. CPC H03F 3/45475; H03F 2200/06; H03F 2200/09; H03F 2200/451

(57) ABSTRACT

A main line (transmission line) has a first end and a second end. A sub-line (transmission line) coupled to the main line has a third end and a fourth end. The main line and the sub-line are coupled to each other. A direction of the main line is identical to a direction of the sub-line. An unbalanced node is connected to the first end. The first balanced node is connected to the first end, and the second balanced node is connected to the fourth end. The second end and the third end are connected to a reference potential. A first LC resonant circuit is connected between the first balanced node and the unbalanced node, the second balanced node and the fourth end, or the first end and the unbalanced node.

### CROSS REFERENCE TO RELATED APPLICATION

This application claims priority from Japanese Patent Application No. 2022-180502 filed on Nov. 10, 2022. The content of this application is incorporated herein by reference in its entirety.

### BACKGROUND

The present disclosure relates to a balanced-unbalanced transformer circuit and an amplifier circuit.

A balanced-unbalanced transformer circuit using a Ruthroff transmission line transformer is known (Hua-Yen Chung, et. al., Design of Step-Down Broadband and Low-Loss Ruthroff-Type Baluns Using IPD Technology, IEEE Trans. on Components, Packing and Manufacturing Technology, Vol. 4, No. 6, JUNE (2014), hereinafter referred to as non-patent document 1). In the balanced-unbalanced transformer circuit disclosed in non-patent document 1, a transmission line for phase compensation is connected between one of two balanced terminals and an unbalanced terminal to compensate for a phase imbalance at a branch point at which a line branches into a main line and a sub-line from the unbalanced terminal.

### BRIEF SUMMARY

The amount of change in the phase of a radio frequency (RF) signal transmitted through a transmission line tends to monotonically increase with respect to the frequency of the RF signal. Thus, it is difficult to perform appropriate phase compensation over a wide frequency band by using the transmission line. As a result, it is difficult to achieve a wider band with the configuration of the balanced-unbalanced transformer circuit described in non-patent document 1.

The present disclosure provides a balanced-unbalanced transformer circuit capable of achieving a wider band. The present disclosure provides an amplifier circuit that is less likely to be affected by an interference wave superimposed on an input signal, by using the balanced-unbalanced transformer circuit.

According to an aspect of the present disclosure, there is provided a balanced-unbalanced transformer circuit including:
a main line constituted by a transmission line having a first end and a second end;
a sub-line coupled to the main line, the sub-line being constituted by a transmission line having a third end and a fourth end;
an unbalanced node to which an unbalanced signal is input and from which the unbalanced signal is output, the unbalanced node being connected to the first end; and
a first balanced node and a second balanced node to which a balanced signal is input and from which the balanced signal is output, in which
the main line and the sub-line are coupled to each other such that a direction from the first end toward the second end of the main line is identical to a direction from the third end toward the fourth end of the sub-line,
the first balanced node is connected to the first end, and the second balanced node is connected to the fourth end,
the second end and the third end are connected to a reference potential, and
the balanced-unbalanced transformer circuit further includes a first LC resonant circuit connected at least one of between the first balanced node and the unbalanced node, between the second balanced node and the fourth end, and between the first end and the unbalanced node.

According to another aspect of the present disclosure, there is provided an amplifier circuit including:
a first balanced-unbalanced transformer circuit configured to transform an unbalanced signal into a balanced signal;
a differential amplifier configured to amplify the balanced signal output from the first balanced-unbalanced transformer circuit; and
a second balanced-unbalanced transformer circuit configured to transform the balanced signal output from the differential amplifier into an unbalanced signal, in which
one of the first balanced-unbalanced transformer circuit and the second balanced-unbalanced transformer circuit is the foregoing balanced-unbalanced transformer circuit, and operates as a balanced-unbalanced transformer circuit for a radio frequency signal of a first frequency and a radio frequency signal of a second frequency, and
an other of the first balanced-unbalanced transformer circuit and the second balanced-unbalanced transformer circuit operates as a balanced-unbalanced transformer circuit for a radio frequency signal of one of the first frequency and the second frequency and does not operate as a balanced-unbalanced transformer circuit for a radio frequency signal of an other of the first frequency and the second frequency.

The first LC resonant circuit has an impedance that is inductive in one of a low frequency band lower than a resonant frequency and a high frequency band higher than the resonant frequency, and that is capacitive in the other. It is possible to find a condition for performing appropriate phase compensation in both the frequency band in which the impedance is inductive and the frequency band in which the impedance is capacitive. This makes it possible to widen the band of the balanced-unbalanced transformer circuit.

A radio frequency signal of a frequency at which both the first balanced-unbalanced transformer circuit and the second balanced-unbalanced transformer circuit operate as a balanced-unbalanced transformer circuit is amplified. When a radio frequency signal of a frequency at which the first balanced-unbalanced transformer circuit operates as a balanced-unbalanced transformer circuit and the second balanced-unbalanced transformer circuit does not operate as a balanced-unbalanced transformer circuit is converted into an unbalanced signal by the second balanced-unbalanced transformer circuit, two balanced signals of the radio frequency signal cancel each other. Thus, it is possible to find a condition for amplifying an input signal and not amplifying an interference wave.

### BRIEF DESCRIPTION OF THE DRAWINGS

FIG. 1 is an equivalent circuit diagram of a balun according to a first embodiment;

FIG. 2 is an equivalent circuit diagram of a balun according to a second embodiment;

FIG. 3A is a schematic perspective view of a main line and a sub-line of the balun according to the second embodiment;

FIG. 3B is a schematic perspective view of the main line, the sub-line, and insulating films;

FIG. 4A and FIG. 4B are each a graph illustrating a simulation result of a common mode rejection ratio (CMRR) obtained when a line length L and an offset amount Off of the main line and the sub-line are changed;

FIG. 5A and FIG. 5B are each a graph illustrating a simulation result of a CMRR obtained when the line length L and the offset amount Off of the main line and the sub-line are changed;

FIG. 6A and FIG. 6B are each a graph illustrating a simulation result of a CMRR obtained when the line length L and the offset amount Off of the main line and the sub-line are changed;

FIG. 7 is a graph illustrating a simulation result of the frequency dependence of CMRR;

FIG. 8A, FIG. 8B, and FIG. 8C are equivalent circuit diagrams of baluns according to modifications of the second embodiment;

FIG. 9A and FIG. 9B are equivalent circuit diagrams of baluns according to other modifications of the second embodiment;

FIG. 10A is an equivalent circuit diagram of a balun according to a third embodiment;

FIG. 10B is an equivalent circuit diagram of a balun according to a modification of the third embodiment;

FIG. 10C is an equivalent circuit diagram of a balun according to another modification of the third embodiment;

FIG. 11 is a block diagram of an amplifier circuit according to a fourth embodiment;

FIG. 12A is an equivalent circuit diagram of an input balun of the amplifier circuit illustrated in FIG. 11;

FIG. 12B is a graph illustrating an example of the frequency dependence of CMRR of the input balun; and

FIG. 13 is a block diagram of an amplifier circuit according to a fifth embodiment.

### DETAILED DESCRIPTION

### First Embodiment

A balanced-unbalanced transformer circuit (hereinafter referred to as a balun) according to a first embodiment will be described with reference to FIG. 1.

FIG. 1 is an equivalent circuit diagram of the balun according to the first embodiment. The balun according to the first embodiment includes a main line 11 and a sub-line 12 each of which is constituted by a transmission line. In FIG. 1, the sub-line 12 is hatched. The main line 11 and the sub-line 12 constitute a Ruthroff transmission line transformer. One end portion of the main line 11 is referred to as a first end EP1, and the other end portion thereof is referred to as a second end EP2. One end portion of the sub-line 12 is referred to as a third end EP3, and the other end portion thereof is referred to as a fourth end EP4. The main line 11 and the sub-line 12 are coupled to each other such that the direction from the first end EP1 toward the second end EP2 of the main line 11 is identical to the direction from the third end EP3 toward the fourth end EP4 of the sub-line 12.

The first end EP1 of the main line 11 is connected to an unbalanced node 21 to which an unbalanced signal is input and from which the unbalanced signal is output. The second end EP2 of the main line 11 is connected to a reference potential (ground potential). The unbalanced node 21 is connected to a first balanced node 22A, which is one of a pair of balanced nodes to which a balanced signal is input and from which the balanced signal is output. A second balanced node 22B, which is the other balanced node, is connected to the fourth end EP4 of the sub-line 12. The third end EP3 of the sub-line 12 is connected to a reference potential. An LC resonant circuit 30 is connected between the first balanced node 22A and the unbalanced node 21. The LC resonant circuit 30 includes an inductor and a capacitor, and has at least one resonant frequency. The LC resonant circuit 30 has a reactance that is capacitive in one of a low frequency band lower than the resonant frequency and a high frequency band higher than the resonant frequency, and that is inductive in the other.

An unbalanced signal is input to the unbalanced node 21 from a radio frequency (RF) signal source 15 having an output impedance Zₛ. A load 18 is connected between the first balanced node 22A and the second balanced node 22B. A current entered through the unbalanced node 21 is divided into a current flowing toward the main line 11 and a current flowing toward the sub-line 12.

The output voltage of the RF signal source 15 is denoted by Vₛ, and the input impedance on the load side as seen from the unbalanced node 21 is denoted by Zin. The load impedance of the load 18 is denoted by Z_{L}. The output impedance on the input side as seen from the first balanced node 22A and the second balanced node 22B is denoted by Zout.

Next, the operation of the balun according to the first embodiment will be described. A current that flows into the balun from the unbalanced node 21 is denoted by I. When an RF current flows through the main line 11, an induced current in an odd mode flows through the sub-line 12. The magnitude of the induced current flowing through the sub-line 12 is equal to the magnitude of the RF current flowing through the main line 11, and the phase of the induced current flowing through the sub-line 12 is inverted with respect to the phase of the RF current flowing through the main line 11. Thus, the RF current I input to the unbalanced node 21 is equally divided into a current flowing through the main line 11 and a current flowing through the sub-line 12. That is, the magnitude of the current flowing through the main line 11 and the magnitude of the current flowing through the sub-line 12 are each equal to ½.

The voltage at the first end EP1 of the main line 11 is denoted by V. The voltage at the second end EP2 of the main line 11 is 0. That is, the potential difference between both ends of the main line 11 is equal to V. At this time, the potential difference between both ends of the sub-line 12 is also equal to V. The voltage at the third end EP3 of the sub-line 12 is 0, and thus the voltage at the fourth end EP4 is equal to −V. That is, the voltage at the first balanced node 22A is V, and the voltage at the second balanced node 22B is −V. The current flowing through the load 18 is equal to ½.

When the voltage at the unbalanced node 21 is V and the current entering through the unbalanced node 21 is I, the potential difference between the first balanced node 22A and the second balanced node 22B is 2 V, and the current flowing through the load 18 is ½. Thus, the output impedance Zout is four times the input impedance Zin. The balun according to the first embodiment transforms an unbalanced signal input from the unbalanced node 21 into a balanced signal and performs impedance conversion.

Alternatively, the first balanced node 22A and the second balanced node 22B may be used as input nodes, and the unbalanced node 21 may be used as an output node. In this case, the balun according to the first embodiment transforms a balanced signal input from the first balanced node 22A and the second balanced node 22B into an unbalanced signal and performs impedance conversion.

The LC resonant circuit 30 compensates for, at the unbalanced node 21, a phase imbalance between the current flowing toward the main line 11 and the current flowing toward the sub-line 12. If only an inductor or only a capacitor is connected instead of the LC resonant circuit 30, the phase imbalance is compensated for in one frequency range based on the inductance of the inductor or the capacitance of the capacitor. Use of the LC resonant circuit 30 makes it possible to compensate for a phase imbalance in two frequency ranges, i.e., a frequency range in which the reactance of the LC resonant circuit 30 is inductive and a frequency range in which the reactance of the LC resonant circuit 30 is capacitive.

Next, excellent effects of the first embodiment will be described.

In the first embodiment, a phase imbalance can be compensated for in two frequency ranges as described above. Thus, it is possible to widen the frequency range in which the balanced-unbalanced transformer circuit is capable of performing balanced-unbalanced transformation.

### Second Embodiment

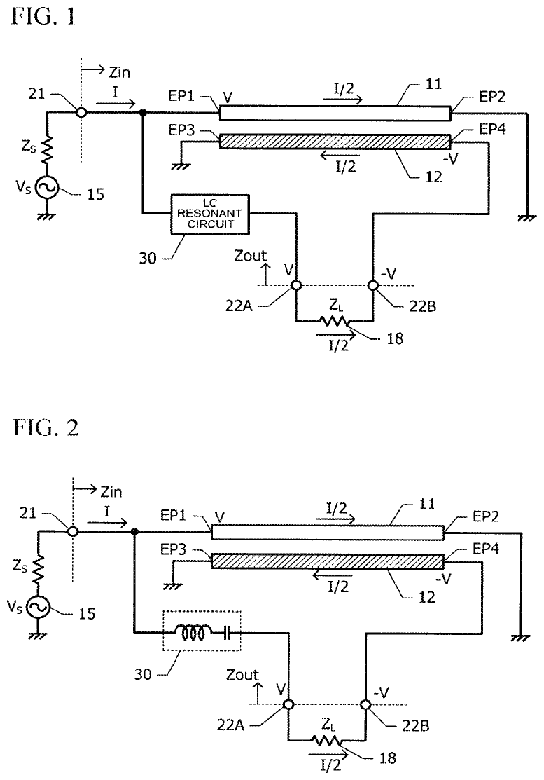

Next, a balun according to a second embodiment will be described with reference to FIG. 2 to FIG. 7.

Hereinafter, a description of the same components as those of the balun according to the first embodiment (FIG. 1) will be omitted.

FIG. 2 is an equivalent circuit diagram of the balun according to the second embodiment. Although a specific circuit configuration of the LC resonant circuit 30 is not described in the first embodiment (FIG. 1), an LC series resonant circuit is used as the LC resonant circuit 30 in the second embodiment.

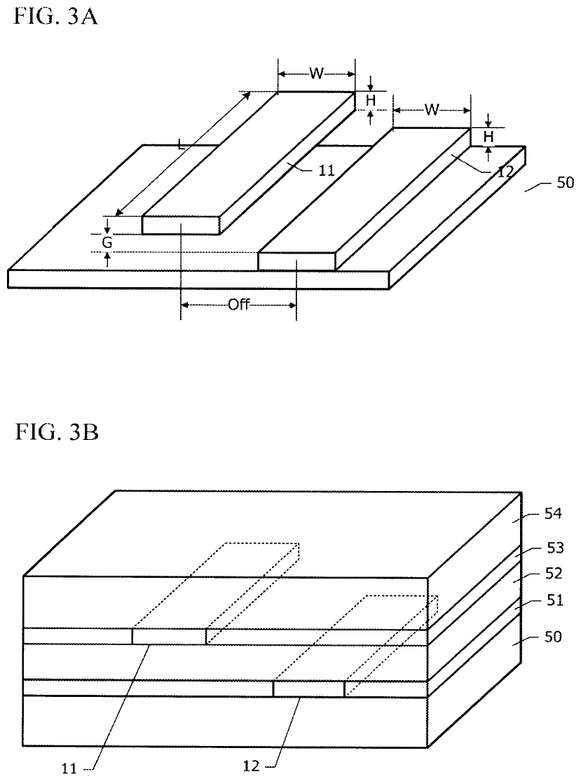

FIG. 3A is a schematic perspective view of the main line 11 and the sub-line 12, and FIG. 3B is a perspective view of the main line 11, the sub-line 12, and insulating films. The main line 11 and the sub-line 12 are constituted by wiring lines in a multilayer wiring structure disposed on an upper surface of a substrate 50, which is one surface of the substrate 50. The main line 11 and the sub-line 12 are disposed in wiring layers different from each other. For example, the sub-line 12 is disposed at a position lower than the main line 11, with the upper surface of the substrate 50 being a reference of height. In plan view, the main line 11 and the sub-line 12 are parallel to each other.

As illustrated in FIG. 3A, the line length, the width, and the height of the main line 11 are denoted by L, W, and H, respectively. The sub-line 12 has a line length L, a width W, and a height H that are equal to the line length L, the width W, and the height H of the main line 11, respectively. The sub-line 12 is disposed so as to be offset in the width direction with respect to the main line 11. The amount of offset is denoted by Off. A gap between the main line 11 and the sub-line 12 in the height direction is denoted by G. In FIGS. 3A and 3B, the main line 11 and the sub-line 12 extend linearly, but both the lines may extend spirally.

As illustrated in FIG. 3B, the sub-line 12 and a first insulating film 51 are disposed on the upper surface of the substrate 50, which is one surface of the substrate 50. The first insulating film 51 has a thickness equal to the height H of the sub-line 12 (FIG. 3A). A second insulating film 52 is disposed on the sub-line 12 and the insulating film 51. The second insulating film 52 has a thickness equal to the gap G (FIG. 3A). The main line 11 and a third insulating film 53 are disposed on the insulating film 52. The third insulating film 53 has a thickness equal to the height H of the main line 11 (FIG. 3A). A fourth insulating film 54 is disposed on the main line 11 and the insulating film 53.

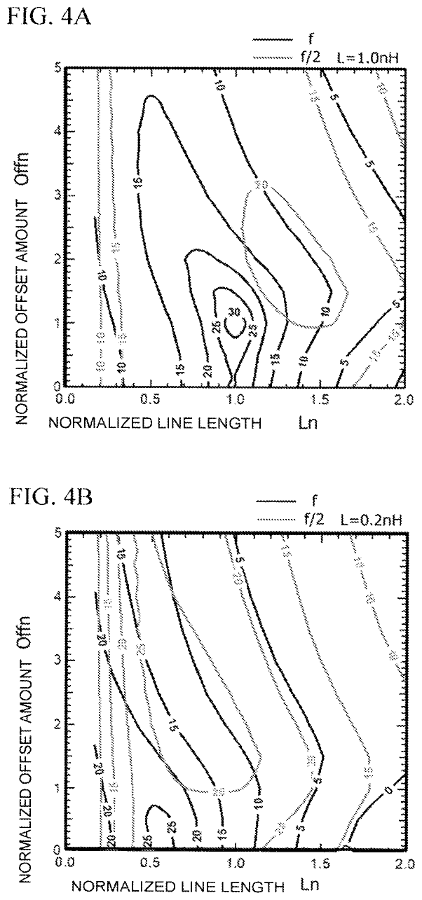

Next, excellent effects of the second embodiment will be described with reference to FIG. 4A to FIG. 7.

FIG. 4A to FIG. 6B are each a graph illustrating a simulation result of a common mode rejection ratio (CMRR) obtained when the line length L and the offset amount Off of the main line 11 and the sub-line 12 are changed. The horizontal axis represents values obtained by normalizing the line length L (normalized line length Ln), and the vertical axis represents values obtained by normalizing the offset amount Off (normalized offset amount Offn). The normalized line length Ln and the normalized offset amount Offn are values normalized so that the line length L and the offset amount Off at which the CMRR has a maximum value when a frequency f is 6150 MHz in FIG. 4A correspond to a reference value 1.

In the graphs in FIG. 4A to FIG. 6B, black solid lines indicate isopleths of the CMRR when the frequency f is 6150 MHz, and gray solid lines indicate isopleths of the CMRR when the frequency f/2 is 3075 MHz. The numerical value attached to each isopleth of the CMRR indicates the value of the CMRR in the unit of dB. The relative permittivities of the substrate 50 and the insulating films 51, 52, 53, and 54 illustrated in FIG. 3B are 3.901, 3.700, 3.848, 3.700, and 5.723, respectively.

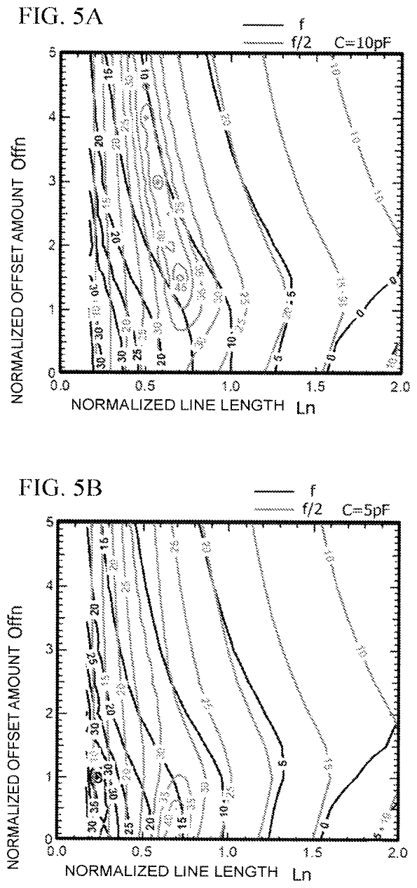

FIG. 4A and FIG. 4B illustrate the CMRRs obtained when an inductor having an inductance of 1.0 nH and an inductor having an inductance of 0.2 nH are connected instead the LC resonant circuit 30 (FIG. 2), respectively. FIG. 5A and FIG. 5B illustrate the CMRRs obtained when a capacitor having a capacitance of 10 pF and a capacitor having a capacitance of 5 pF are connected instead of the LC resonant circuit 30 (FIG. 2), respectively.

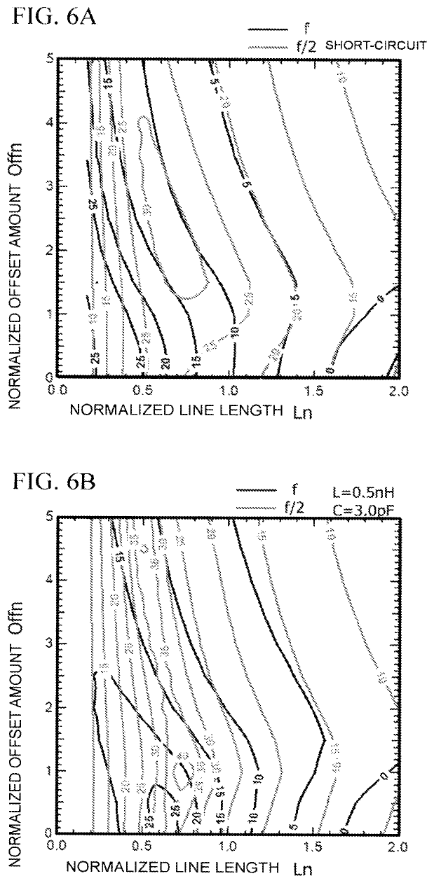

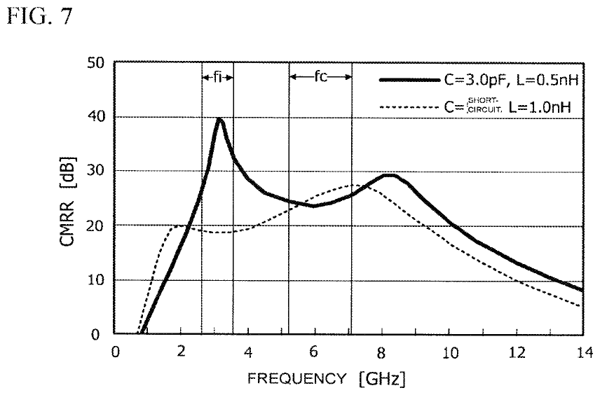

FIG. 6A illustrates the CMRR obtained when the portion of the LC resonant circuit 30 (FIG. 2) is short-circuited. FIG. 6B illustrates the CMRR obtained when the LC resonant circuit 30 (FIG. 2) has an inductance of 0.5 nH and a capacitance of 3 pF.

In the graphs in FIG. 4A to FIG. 6B, a condition in which the normalized offset amount Offn is 1.25 corresponds to a condition in which the offset amount Off is equal to the width W of each of the main line 11 and the sub-line 12. That is, in the range in which the normalized offset amount Offn is smaller than 1.25, a part of the main line 11 in the width direction overlaps a part of the sub-line 12 in the width direction in plan view. In the range in which the normalized offset amount Offn is 1.25 or more, the sub-line 12 does not overlap the main line 11 in plan view.

As illustrated in FIG. 6A, when the portion of the LC resonant circuit 30 is short-circuited and the balun is operated at the frequency f/2, the CMRR has a maximum value in the vicinity of the normalized line length Ln of about 0.7 and the normalized offset amount Offn of 2.5. However, when the balun is operated at the frequency f, the CMRR is low in this range. That is, the balun operates as a balun at the frequency f/2, but does not operate as a balun at the frequency f.

As illustrated in FIG. 4A and FIG. 4B, when an inductor is connected instead of the LC resonant circuit 30, it is possible to realize a condition in which the CMRR has a maximum value with respect to an RF signal of the frequency f in the range in which the normalized line length Ln is 0.5 or more and 1.1 or less and the normalized offset amount Offn is 0 or more and 1.2 or less. However, in this range, the CMRR decreases with respect to an RF signal of the frequency f/2. This is because, at the unbalanced node 21, the phase imbalance between the current flowing toward the main line 11 and the current flowing toward the sub-line 12 is compensated for with respect to an RF signal of the frequency f, but the phase imbalance is not compensated for with respect to an RF signal of the frequency f/2. In this specification, “compensation for phase imbalance” includes compensation for decreasing the degree of phase imbalance and increasing the degree of phase balance, in addition to compensation for completely balancing the phases of the current flowing toward the main line 11 and the current flowing toward the sub-line 12. “Compensation for phase imbalance” may be simply referred to as “phase compensation”.

As illustrated in FIG. 5A and FIG. 5B, when a capacitor is connected instead of the LC resonant circuit 30, it is possible to realize a condition in which the CMRR has a maximum value with respect to an RF signal of the frequency f/2 under a condition in which the normalized line length Ln is about 0.7. However, in this condition, the CMRR decreases with respect to an RF signal of the frequency f. This is because, at the unbalanced node 21, the phase imbalance is compensated for with respect to an RF signal of the frequency f/2, but the phase imbalance is not compensated for with respect to an RF signal of the frequency f.

In the above-described configuration in which an inductor or a capacitor is connected instead of the LC resonant circuit 30, it is difficult to compensate for the phase imbalance at the unbalanced node 21 with respect to both of an RF signal of the frequency f and an RF signal of the frequency f/2.

Under the condition illustrated in the graph in FIG. 6B, the resonant frequency 4109 MHz of the LC resonant circuit 30 is between the frequency f of 6150 MHz and the frequency f/2 of 3075 MHz. Thus, the impedance of the LC resonant circuit 30 is inductive at the frequency f and is capacitive at the frequency f/2. Thus, it is possible to compensate for the phase imbalance at the unbalanced node 21 for both an RF signal of the frequency f and an RF signal of the frequency f/2.

As illustrated in FIG. 6B, when the normalized line length Ln is about 0.7 and the normalized offset amount Offn is in the range of about 0.5 or more and 1 or less, a high CMRR is obtained for both RF signals of the frequencies f and f/2. As a result of connecting the LC resonant circuit 30 in this manner, the phase imbalance at the unbalanced node 21 can be compensated for with respect to RF signals of two frequencies on both sides of the resonant frequency, and a high CMRR can be obtained. In other words, it is possible to implement a wide band balun capable of performing balanced-unbalanced transformation in two frequency bands.

FIG. 7 is a graph illustrating a simulation result of the frequency dependence of CMRR. The horizontal axis represents frequency in the unit of GHz, and the vertical axis represents CMRR in the unit of dB. In the graph, the solid line indicates the CMRR obtained when the LC resonant circuit 30 has a capacitance of 3.0 pF and an inductance of 0.5 nH, and the broken line indicates the CMRR obtained in a configuration in which an inductor having an inductance of 1.0 nH is connected instead of the LC resonant circuit 30 (i.e., a configuration in which the capacitor is short-circuited).

In the configuration in which an inductor is connected instead of the LC resonant circuit 30, a high CMRR is obtained in the frequency band fc including the frequency f of 6150 MHz, but the CMRR is low in the frequency band fi including the frequency f/2 of 3075 MHz. In contrast, in the configuration in which the LC resonant circuit 30 is connected as in the second embodiment, a CMRR equivalent to the characteristic indicated by the broken line is maintained in the frequency band fc, and a CMRR sufficiently higher than the characteristic indicated by the broken line is obtained in the frequency band fi. Specifically, in the frequency band fi, the CMRR is improved by about 20 dB at the maximum.

The simulation conditions in the simulations illustrated in FIG. 4A to FIG. 7 are examples. Suitable values of the line length L, the width W, the height H, the gap G, and the offset amount Off of the main line 11 and the sub-line 12 can be determined by performing various simulations or evaluation experiments in accordance with a frequency band to be handled and a target CMRR.

As described above, in the second embodiment, the connection of the LC resonant circuit 30 makes it possible to realize a high CMRR in two frequency bands on both sides of the resonant frequency of the LC resonant circuit 30. That is, the balun according to the second embodiment is capable of performing balanced-unbalanced transformation in two frequency bands.

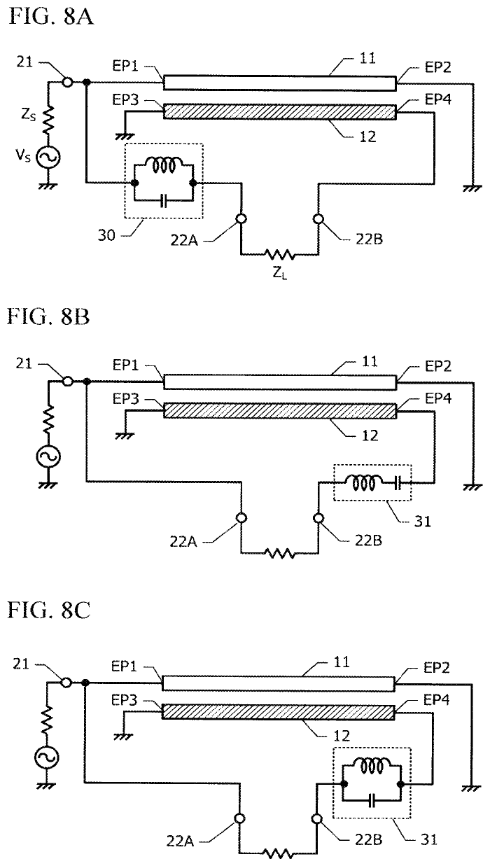

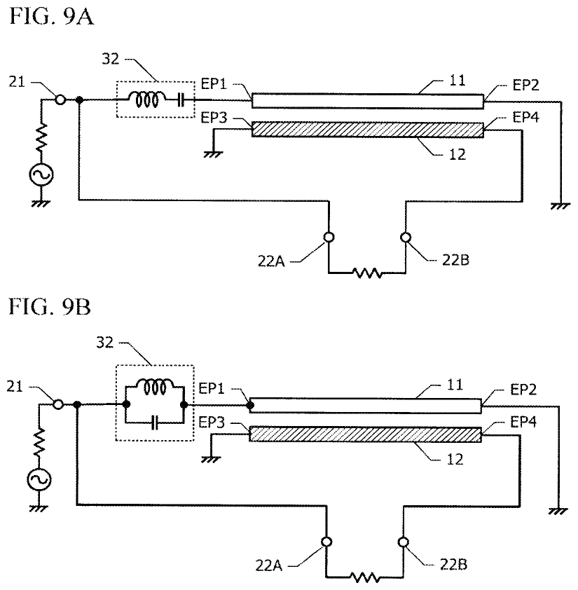

Next, baluns according to modifications of the second embodiment will be described with reference to FIG. 8A to FIG. 9B. FIG. 8A, FIG. 8B, FIG. 8C, FIG. 9A, and FIG. 9B are equivalent circuit diagrams of baluns according to modifications of the second embodiment.

In the second embodiment (FIG. 2), an LC series resonant circuit is used as the LC resonant circuit 30. In contrast, in the modification illustrated in FIG. 8A, an LC parallel resonant circuit is used as the LC resonant circuit 30. Also in the LC parallel resonant circuit, both a capacitive impedance and an inductive impedance are realized with the resonant frequency as a boundary. Thus, similarly to the second embodiment, the phase imbalance at the branch point at which the line branches into the main line 11 and the sub-line 12 from the unbalanced node 21 can be appropriately compensated for in two frequencies. Accordingly, the balun according to the modification illustrated in FIG. 8A is capable of performing balanced-unbalanced transformation in two frequency bands.

In the second embodiment (FIG. 2), the LC resonant circuit 30 is connected between the first balanced node 22A and the unbalanced node 21. In contrast, in the modifications illustrated in FIG. 8B and FIG. 8C, the first balanced node 22A and the unbalanced node 21 are short-circuited to each other, and an LC resonant circuit 31 is connected between the second balanced node 22B and the fourth end EP4 of the sub-line 12. In the modification illustrated in FIG. 8B, an LC series resonant circuit is used as the LC resonant circuit 31. In the modification illustrated in FIG. 8C, an LC parallel resonant circuit is used as the LC resonant circuit 31.

In the modifications illustrated in FIG. 9A and FIG. 9B, an LC resonant circuit 32 is connected between the unbalanced node 21 and the first end EP1 of the main line 11. The first balanced node 22A is short-circuited to the unbalanced node 21, and the second balanced node 22B is short-circuited to the fourth end EP4. In the modification illustrated in FIG. 9A, an LC series resonant circuit is used as the LC resonant circuit 32. In the modification illustrated in FIG. 9B, an LC parallel resonant circuit is used as the LC resonant circuit 32.

Also in the modifications illustrated in FIG. 8B, FIG. 8C, FIG. 9A, and FIG. 9B, the phase imbalance at the unbalanced node 21 can be compensated for.

Although an LC series resonant circuit or an LC parallel resonant circuit is used as each of the LC resonant circuits 30, 31, and 32 in the second embodiment (FIG. 2) and the modifications of the second embodiment described with reference to FIG. 8A to FIG. 9B, an LC resonant circuit having another configuration may be used. For example, a circuit that includes one or more inductors and one or more capacitors, has one or more resonant frequencies, and realizes both of a capacitive impedance and an inductive impedance with the resonant frequency as a boundary may be used.

### Third Embodiment

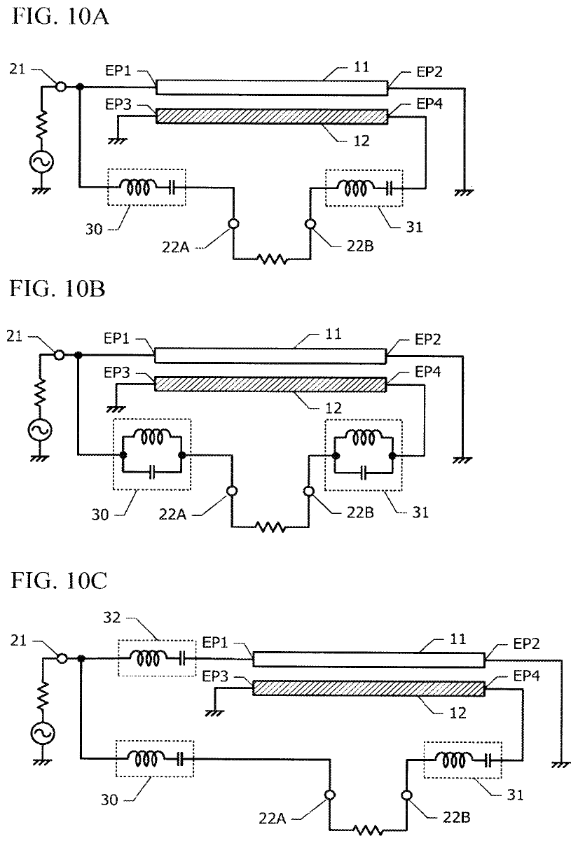

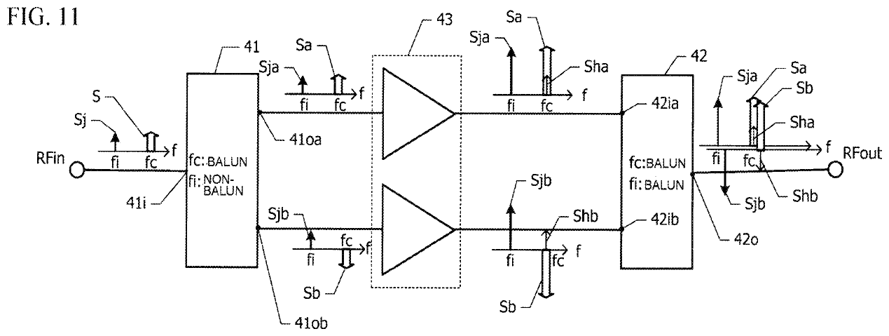

Next, a balun according to a third embodiment will be described with reference to FIG. 10A. Hereinafter, a description of the same components as those of the baluns according to the second embodiment and the modifications thereof described with reference to FIG. 2 to FIG. 9B will be omitted.

FIG. 10A is an equivalent circuit diagram of the balun according to the third embodiment. In the second embodiment (FIG. 2), the LC resonant circuit 30 is connected between the first balanced node 22A and the unbalanced node 21. In the modification illustrated in FIG. 8B, the LC resonant circuit 31 is connected between the second balanced node 22B and the fourth end EP4. In the modification illustrated in FIG. 9A, the LC resonant circuit 32 is connected between the first end EP1 and the unbalanced node 21.

In contrast, in the third embodiment, the LC resonant circuit 30 is connected between the first balanced node 22A and the unbalanced node 21, and the LC resonant circuit 31 is connected between the second balanced node 22B and the fourth end EP4. Each of the LC resonant circuits 30 and 31 is an LC series resonant circuit.

Next, excellent effects of the third embodiment will be described.

Also in the third embodiment, similarly to the second embodiment, it is possible to perform balanced-unbalanced transformation in two frequency bands by compensating for the phase imbalance at the unbalanced node 21. Furthermore, in the third embodiment, the amount of phase compensation can be individually optimized at each of the first balanced node 22A and the second balanced node 22B. This makes it possible to obtain an excellent effect that the degree of freedom in adjusting the phase of a balanced signal with respect to the phase of an unbalanced signal is increased.

When the resonant frequency of one LC resonant circuit 30 is different from the resonant frequency of the other LC resonant circuit 31, it is possible to compensate for a phase imbalance in two frequency bands on the low frequency side and the high frequency side of one of the resonant frequencies and in two frequency bands on the low frequency side and the high frequency side of the other resonant frequency. Accordingly, it is possible to implement a balun that performs balanced-unbalanced transformation in more than two frequency bands. That is, a wider band balun can be implemented.

Next, a balun according to a modification of the third embodiment will be described with reference to FIG. 10B. FIG. 10B is an equivalent circuit diagram of the balun according to the modification of the third embodiment. In the third embodiment, an LC series resonant circuit is used as each of the LC resonant circuits 30 and 31. In the modification illustrated in FIG. 10B, an LC parallel resonant circuit is used as each of the LC resonant circuits 30 and 31. Alternatively, an LC series resonant circuit may be used as one of the LC resonant circuits 30 and 31, and an LC parallel resonant circuit may be used as the other.

Next, a balun according to another modification of the third embodiment will be described with reference to FIG. 10C. FIG. 10C is an equivalent circuit diagram of the balun according to the other modification of the third embodiment. In the third embodiment (FIG. 10A), the LC resonant circuit 30 is connected between the first balanced node 22A and the unbalanced node 21, and the LC resonant circuit 31 is connected between the second balanced node 22B and the fourth end EP4. In contrast, in the modification illustrated in FIG. 10C, the LC resonant circuit 32 is further connected between the first end EP1 and the unbalanced node 21. That is, the LC resonant circuits 30, 31, and 32 are connected at three respective positions. Either an LC series resonant circuit or an LC parallel resonant circuit may be used as each of the LC resonant circuits 30, 31, and 32. Alternatively, an LC series resonant circuit and an LC parallel resonant circuit may be used in combination as the LC resonant circuits 30, 31, and 32.

In this way, as a result of connecting the LC resonant circuits 30, 31, and 32 at three respective positions, it is possible to further widen the band of the balun.

### Fourth Embodiment

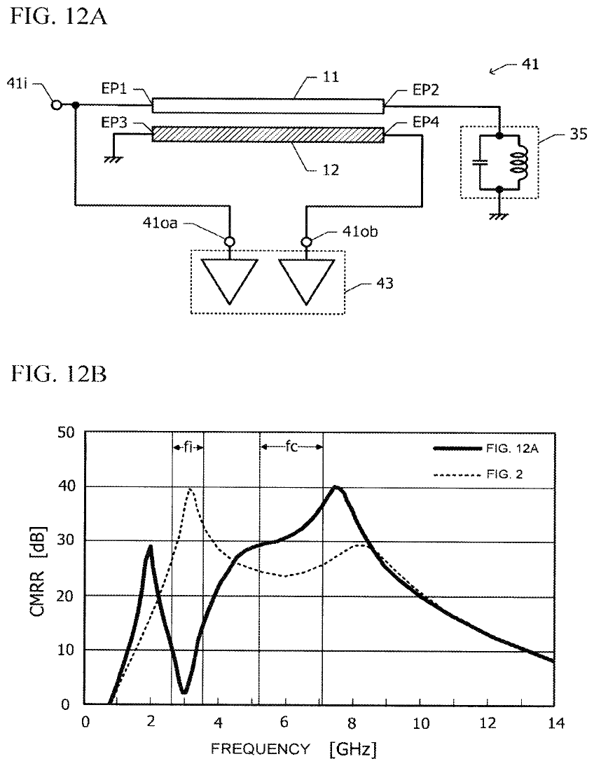

An amplifier circuit according to a fourth embodiment will be described with reference to FIG. 11, FIG. 12A, and FIG. 12B. The amplifier circuit according to the fourth embodiment is equipped with the balun according to any one of the second embodiment, the third embodiment, and the modifications thereof.

FIG. 11 is a block diagram of the amplifier circuit according to the fourth embodiment. The amplifier circuit according to the fourth embodiment includes an input balun 41, a differential amplifier 43, and an output balun 42. An unbalanced signal input from an input terminal RFin is input to an unbalanced node 41i of the input balun 41. The input balun 41 transforms the unbalanced frequency signal into a balanced signal. The balanced signal obtained through the transformation is output from a pair of balanced nodes 41oa and 41ob. The balanced signal output from the input balun 41 is amplified by the differential amplifier 43 and is input to balanced nodes 42ia and 42ib of the output balun 42. The output balun 42 transforms the balanced signal into an unbalanced signal. The unbalanced signal obtained through the transformation is output from an unbalanced node 42o. The unbalanced node 42o of the output balun 42 is connected to an output terminal RFout.

The input balun 41 operates as a balun for an RF signal in the frequency band fc, but does not operate as a balun for an RF signal in the frequency band fi, which is ½ of the frequency band fc. For example, when the CMRR is 20 dB or less, the input balun 41 does not operate as a balun.

The balun according to the second embodiment, the third embodiment, or one of the modifications thereof is used as the output balun 42. For example, the unbalanced node 42o, the balanced node 42ia, and the balanced node 42ib of the output balun 42 correspond to the unbalanced node 21, the first balanced node 22A, and the second balanced node 22B of the baluns (FIG. 10A) according to the second embodiment, the third embodiment, and the modifications thereof, respectively. The output balun 42 operates as a balun in both the frequency band fc and the frequency band fi, which is ½ of the frequency band fc.

In FIG. 11, the graphs illustrated between the input terminal RFin and the input balun 41, between the input balun 41 and the differential amplifier 43, between the differential amplifier 43 and the output balun 42, and between the output balun 42 and the output terminal RFout schematically show the magnitudes and phases of RF signals in the frequency bands fi and fc. The horizontal axis represents frequency. The vertical axis represents signal magnitude. An upward arrow and a downward arrow mean that the phases are inverted with respect to each other.

Next, the operation of the amplifier circuit according to the fourth embodiment will be described. An input signal S in the frequency band fc is input to the input balun 41. In addition to the input signal S, an interference wave Sj in the frequency band fi is also input. For example, the frequency of the frequency band fi of the interference wave Sj is ½ of the frequency of the frequency band fc of the input signal S.

As an example, a frequency band of ½ of the frequencies of band UNII-1 (5150 MHz or more and 5250 MHz or less) and band UNII-2 (5250 MHz or more and 5350 MHz or less) of Wi-Fi overlaps the cellular band B41 (frequencies of 2496 MHz or more and 2690 MHz or less). Thus, an RF signal in the cellular band B41 may become an interference wave with respect to RF signals in the bands UNII-1 and UNII-2 of Wi-Fi. In addition, a frequency band of ½ of the frequencies of band UNII-7 (6525 MHz or more and 6875 MHz or less) and band UNII-8 (6875 MHz or more and 7125 MHz or less) of Wi-Fi overlaps the cellular band N77 (frequencies of 3300 MHz or more and 4200 MHz or less). Thus, an RF signal in the cellular band N77 may become an interference wave with respect to RF signals in the bands UNII-7 and UNII-8 of Wi-Fi.

The input signal S is transformed into a balanced signal by the input balun 41, and RF signals Sa and Sb are output from the balanced nodes 41oa and 41ob, respectively. The phases of the RF signals Sa and Sb are inverted with respect to each other. In the frequency band fi of the interference wave Sj, the input balun 41 does not operate as a balun, and thus interference waves Sja and Sjb having the same phase are output from the two balanced nodes 41oa and 41ob, respectively.

The RF signal Sa and the interference wave Sja are amplified by one amplifier of the differential amplifier 43, and the amplified RF signal Sa and interference wave Sja are output. The RF signal Sb and the interference wave Sjb are amplified by the other amplifier of the differential amplifier 43, and the amplified RF signal Sb and interference wave Sjb are output. The two amplifiers constituting the differential amplifier 43 have the same gain and the same phase characteristics. Thus, the magnitudes of the amplified RF signals Sa and Sb are equal to each other, and the phase of the amplified RF signal Sb remains inverted with respect to the phase of the RF signal Sa. The magnitudes of the amplified interference waves Sja and Sjb are equal to each other, and both the interference waves remain in phase.

Furthermore, the nonlinearity of the differential amplifier 43 produces second-order harmonics Sha and Shb of the interference waves Sja and Sjb. The phases of even-order harmonics of the interference waves Sja and Sjb are the same regardless of the phase relationship between the interference waves Sja and Sjb. Thus, the second-order harmonics Sha and Shb are in phase.

The RF signal Sa, the interference wave Sja, and the second-order harmonic Sha output from the differential amplifier 43 are input to one balanced node 42ia of the output balun 42, and the RF signal Sb, the interference wave Sjb, and the second-order harmonic Shb are input to the other balanced node 42ib of the output balun 42. These signals are transformed into unbalanced signals by the output balun 42. The output balun 42 operates as a balun for signals in both the frequency bands fi and fc. Thus, the RF signal Sa, the interference wave Sja, and the second-order harmonic Sha input to one balanced node 42ia are output with the phases thereof not being inverted, and the RF signal Sb, the interference wave Sjb, and the second-order harmonic Shb input to the other balanced node 42ib are output with the phases thereof being inverted.

The interference waves Sja and Sjb output from the unbalanced node 42o of the output balun 42 cancel each other because the phases thereof are inverted with respect to each other. The second-order harmonics Sha and Shb output from the unbalanced node 42o of the output balun 42 cancel each other because the phases thereof are inverted with respect to each other. The RF signals Sa and Sb output from the unbalanced node 42o of the output balun 42 are in phase and are thus added together.

Next, an example of the input balun 41 (FIG. 11) will be described with reference to FIG. 12A and FIG. 12B. FIG. 12A is an equivalent circuit diagram of the input balun 41 (FIG. 11). The main line 11 and the sub-line 12 constitute a Ruthroff transmission line transformer. The first end EP1 of the main line 11 is connected to the unbalanced node 41i, and the second end EP2 is connected to a reference potential via an LC resonant circuit 35. An LC parallel resonant circuit is used as the LC resonant circuit 35.

The third end EP3 of the sub-line 12 is connected to a reference potential, and the fourth end EP4 is connected to one balanced node 41ob. The other balanced node 41oa is connected to the unbalanced node 41i. The balanced nodes 41oa and 41ob are connected to input terminals of the differential amplifier 43.

The LC resonant circuit 35 has an infinite impedance at the resonant frequency. Thus, the second end EP2 of the main line 11 is disconnected from the reference potential at the resonant frequency of the LC resonant circuit 35. Thus, the input balun 41 does not operate as a balun at the resonant frequency of the LC resonant circuit 35.

FIG. 12B is a graph illustrating an example of the frequency dependence of the CMRR of the input balun 41. The horizontal axis represents frequency in the unit of GHz, and the vertical axis represents CMRR in the unit of dB. In the graph in FIG. 12B, the solid line indicates the CMRR of the balun illustrated in FIG. 12A, and the broken line (identical to the solid line in the graph in FIG. 7) indicates the CMRR of the balun according to the second embodiment illustrated in FIG. 2. The LC resonant circuit 35 has a resonant frequency of about 3 GHz.

In the balun illustrated in FIG. 12A, in the frequency band fi including a frequency of 3 GHz, the CMRR has a minimum value, and the input balun 41 does not operate as a balun. In the frequency band fc of the input signal S, the CMRR is high, and the input balun 41 operates as a balun.

Next, excellent effects of the fourth embodiment will be described.

In the amplifier circuit according to the fourth embodiment, the interference waves Sja and Sjb cancel each other, and the second-order harmonics Sha and Shb cancel each other. Thus, it is possible to reduce deterioration of the noise figure. This makes it possible to implement an amplifier, for example, an RF amplifier, which is less likely to be affected by the interference wave Sj. Furthermore, it is not necessary to insert a filter for reducing an interference wave in the circuit on the input side of the differential amplifier 43, and thus the insertion loss of the filter does not occur. As a result, a required gain of the differential amplifier 43 is reduced, and the current consumption can be reduced.

### Fifth Embodiment

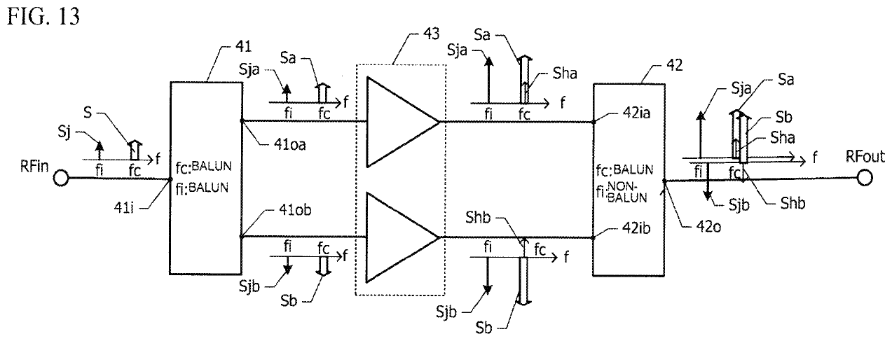

Next, an amplifier circuit according to a fifth embodiment will be described with reference to FIG. 13. Hereinafter, a description of the same components as those of the amplifier circuit according to the fourth embodiment described with reference to FIG. 11, FIG. 12A, and FIG. 12B will be omitted.

FIG. 13 is a block diagram of the amplifier circuit according to the fifth embodiment. In the fourth embodiment (FIG. 11), the input balun 41 operates as a balun in the frequency band fc, and does not operate as a balun in the frequency band fi. In contrast, in the fifth embodiment, the balun according to the second embodiment, the third embodiment, or one of the modifications thereof is used as the input balun 41, and the input balun 41 operates as a balun in both the frequency bands fc and fi. In the fourth embodiment (FIG. 11), the output balun 42 operates as a balun in both the frequency bands fc and fi. In contrast, in the fifth embodiment, the output balun 42 operates as a balun in the frequency band fc, and does not operate as a balun in the frequency band fi. For example, the balun illustrated in FIG. 12A is used as the output balun 42. In the fourth embodiment (FIG. 11), the input balun 41 does not operate as a balun in the frequency band fi, and thus the interference waves Sja and Sjb output from the pair of balanced nodes 41oa and 41ob are in phase. In contrast, in the fifth embodiment, the input balun 41 operates as a balun also in the frequency band fi. Thus, the phase of the interference wave Sjb output from one balanced node 41ob is inverted with respect to the phase of the interference wave Sja output from the other balanced node 41oa. The phase of the interference wave Sjb amplified by the differential amplifier 43 is also inverted with respect to the phase of the interference wave Sja.

Even if the phases of the interference waves Sja and Sjb are inverted with respect to each other, the second-order harmonics Sha and Shb of the interference waves Sja and Sjb are in phase.

The output balun 42 does not operate as a balun in the frequency band fi, and thus the phase of the interference wave Sjb output from the unbalanced node 42o of the output balun 42 remains inverted with respect to the phase of the interference wave Sja. The output balun 42 operates as a balun in the frequency band fc, and thus the interference waves Sja and Sjb that are in phase when being input to the output balun 42 have phases inverted with respect to each other when being output from the unbalanced node 42o. The phase relationship between the RF signals Sa and Sb is the same as the phase relationship between these signals in the amplifier circuit according to the fourth embodiment (FIG. 11).

Thus, also in the fifth embodiment, the interference waves Sja and Sjb output from the unbalanced node 42o cancel each other, and the second-order harmonics Sha and Shb cancel each other. Thus, it is possible to reduce deterioration of the noise figure and an increase in current consumption. This makes it possible to implement an amplifier, for example, an RF amplifier, which is less likely to be affected by the interference wave Sj.

Each of the above-described embodiments is an example, and it is obviously possible to partially replace or combine the elements illustrated in different embodiments. Similar functions and effects obtained from similar configurations of a plurality of embodiments are not repeatedly described in each embodiment. Furthermore, the present disclosure is not limited to the embodiments described above. For example, it will be obvious to those skilled in the art that various modifications, improvements, combinations, and the like are possible.

On the basis of the above embodiments described in this specification, the following disclosures are disclosed.
<1>

A balanced-unbalanced transformer circuit including:
a main line constituted by a transmission line having a first end and a second end;
a sub-line coupled to the main line, the sub-line being constituted by a transmission line having a third end and a fourth end;
an unbalanced node to which an unbalanced signal is input and from which the unbalanced signal is output, the unbalanced node being connected to the first end; and
a first balanced node and a second balanced node to which a balanced signal is input and from which the balanced signal is output, in which
the main line and the sub-line are coupled to each other such that a direction from the first end toward the second end of the main line is identical to a direction from the third end toward the fourth end of the sub-line,
the first balanced node is connected to the first end, and the second balanced node is connected to the fourth end,
the second end and the third end are connected to a reference potential, and
the balanced-unbalanced transformer circuit further includes a first LC resonant circuit connected at least one of between the first balanced node and the unbalanced node, between the second balanced node and the fourth end, and between the first end and the unbalanced node.
<2>

The balanced-unbalanced transformer circuit according to <1>, in which the first LC resonant circuit is an LC series resonant circuit.
<3>

The balanced-unbalanced transformer circuit according to <1>, in which the first LC resonant circuit is an LC parallel resonant circuit.
<4>

The balanced-unbalanced transformer circuit according to any one of <1> to <3>, further including a second LC resonant circuit connected at least one of between the first balanced node and the first end, between the second balanced node and the fourth end, and between the first end and the unbalanced node, the second LC resonant circuit being disposed where the first LC resonant circuit is not disposed.
<5>

An amplifier circuit including:
a first balanced-unbalanced transformer circuit configured to transform an unbalanced signal into a balanced signal;
a differential amplifier configured to amplify the balanced signal output from the first balanced-unbalanced transformer circuit; and
a second balanced-unbalanced transformer circuit configured to transform the balanced signal output from the differential amplifier into an unbalanced signal, in which
one of the first balanced-unbalanced transformer circuit and the second balanced-unbalanced transformer circuit is the balanced-unbalanced transformer circuit according to any one of <1> to <4>, and operates as a balanced-unbalanced transformer circuit for a radio frequency signal of a first frequency and a radio frequency signal of a second frequency, and
an other of the first balanced-unbalanced transformer circuit and the second balanced-unbalanced transformer circuit operates as a balanced-unbalanced transformer circuit for a radio frequency signal of one of the first frequency and the second frequency and does not operate as a balanced-unbalanced transformer circuit for a radio frequency signal of an other of the first frequency and the second frequency.

What is claimed is:

1. A balanced-unbalanced transformer circuit comprising:
a main line constituted by a first transmission line having a first end and a second end;
a sub-line coupled to the main line, the sub-line being constituted by a second transmission line having a third end and a fourth end;
an unbalanced node to which an unbalanced signal is input and from which the unbalanced signal is output, the unbalanced node being connected to the first end;
a first balanced node and a second balanced node to which a balanced signal is input and from which the balanced signal is output; and
a first LC resonant circuit connected between the first balanced node and the unbalanced node, between the second balanced node and the fourth end, or between the first end and the unbalanced node,
wherein the main line and the sub-line are coupled to each other such that a direction from the first end toward the second end of the main line is identical to a direction from the third end toward the fourth end of the sub-line,
wherein the first balanced node is connected to the first end, and the second balanced node is connected to the fourth end, and
wherein the second end and the third end are connected to a reference potential.

2. The balanced-unbalanced transformer circuit according to claim 1, wherein the first LC resonant circuit is an LC series resonant circuit.

3. The balanced-unbalanced transformer circuit according to claim 1, wherein the first LC resonant circuit is an LC parallel resonant circuit.

4. The balanced-unbalanced transformer circuit according to claim 1, further comprising:
a second LC resonant circuit connected between the first balanced node and the first end, between the second balanced node and the fourth end, or between the first end and the unbalanced node,
wherein the second LC resonant circuit is disposed where the first LC resonant circuit is not disposed.

5. The balanced-unbalanced transformer circuit according to claim 2, further comprising:
a second LC resonant circuit connected between the first balanced node and the first end, between the second balanced node and the fourth end, or between the first end and the unbalanced node,
wherein the second LC resonant circuit is disposed where the first LC resonant circuit is not disposed.

6. The balanced-unbalanced transformer circuit according to claim 3, further comprising:
a second LC resonant circuit connected between the first balanced node and the first end, between the second balanced node and the fourth end, or between the first end and the unbalanced node,
wherein the second LC resonant circuit is disposed where the first LC resonant circuit is not disposed.

7. An amplifier circuit comprising:
a first balanced-unbalanced transformer circuit configured to transform a first unbalanced signal into a balanced signal, and to output the balanced signal;
a differential amplifier configured to amplify the balanced signal output from the first balanced-unbalanced transformer circuit; and
a second balanced-unbalanced transformer circuit configured to transform the balanced signal output from the differential amplifier into a second unbalanced signal,
wherein one of the first balanced-unbalanced transformer circuit and the second balanced-unbalanced transformer circuit is the balanced-unbalanced transformer circuit according to claim 1, and is configured to operate on a radio frequency signal of a first frequency and a radio frequency signal of a second frequency, and
wherein the other of the first balanced-unbalanced transformer circuit and the second balanced-unbalanced transformer circuit is configured to operate as a balanced-unbalanced transformer circuit on the radio frequency signal of one of the first frequency and the second frequency and not on the radio frequency signal of the other of the first frequency and the second frequency.

8. An amplifier circuit comprising:
a first balanced-unbalanced transformer circuit configured to transform a first unbalanced signal into a balanced signal, and to output the balanced signal;
a differential amplifier configured to amplify the balanced signal output from the first balanced-unbalanced transformer circuit; and
a second balanced-unbalanced transformer circuit configured to transform the balanced signal output from the differential amplifier into a second unbalanced signal,
wherein one of the first balanced-unbalanced transformer circuit and the second balanced-unbalanced transformer circuit is the balanced-unbalanced transformer circuit according to claim 4, and is configured to operate as a balanced-unbalanced transformer circuit on a radio frequency signal of a first frequency and a radio frequency signal of a second frequency, and
wherein the other of the first balanced-unbalanced transformer circuit and the second balanced-unbalanced transformer circuit is configured to operate as a balanced-unbalanced transformer circuit on the radio frequency signal of one of the first frequency and the second frequency and not on the radio frequency signal of the other of the first frequency and the second frequency.
